(19) United States
(12) Patent Application Publication
(10) Pub. No.: US 2026/0100221 A1
(43) Pub. Date: Apr. 9, 2026

(54) COMPUTE-IN-MEMORY CIRCUITS AND METHODS FOR OPERATING THE SAME

(71) Applicant: Taiwan Semiconductor Manufacturing Company, Ltd., Hsinchu (TW)

(72) Inventors: Wei-Xiang You, Hsinchu City (TW); Lu Yang, Hsinchu City (TW); Szuya Liao, Hsinchu City (TW)

(73) Assignee: Taiwan Semiconductor Manufacturing Company, Ltd., Hsinchu (TW)

(21) Appl. No.: 19/171,553

(22) Filed: Apr. 7, 2025

Related U.S. Application Data
(60) Provisional application No. 63/704,294, filed on Oct. 7, 2024.

(51) Int. Cl. G11C 11/418; G11C 11/419; H03K 19/017

(52) U.S. Cl. CPC G11C 11/418; G11C 11/419; H03K 19/01721

(57) ABSTRACT

An 8T CFET SRAM is proposed to perform the parallel weighted-sum operation to speed-up the inference process. A circuit includes a memory array including memory cells, each of the memory cells including a plurality of transistors, and coupled to a first word line and a second word line, and configured to receive a first data element, store a second data element, and provide a multiplication value of the first data element and the second data element. The first word line is configured to receive a first logic state corresponding to the first data element being binarized, and the second word line is configured to receive a second logic state corresponding to the first data element being binarized. A first internal node among the transistors is configured to store a first logic state corresponding to the second data element being binarized, and a second internal node among the transistors is configured to store a second logic state corresponding to the second data element being binarized.

### CROSS-REFERENCE TO RELATED APPLICATION

This application claims priority to and the benefit of U.S. Provisional Application No. 63/704,294, filed Oct. 7, 2024, which is incorporated herein by reference in its entirety for all purposes.

### BACKGROUND

Artificial intelligence (AI), or machine learning (ML), is a powerful tool that can be used to simulate human intelligence in machines that are programmed to think and act like humans. AI can be used in a variety of applications and industries. AI accelerators are hardware devices that are used for efficient processing of AI workloads like neural networks. One type of AI accelerator includes a systolic array that can perform operations on inputs via multiplication and accumulate operations.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of an example neural network, in accordance with some embodiments.

FIG. 2 illustrates a block diagram of a memory circuit, in accordance with some embodiments.

FIG. 3 illustrates a circuit diagram of a memory cell of the memory circuit of FIG. 2, in accordance with some embodiments.

FIG. 4 illustrates another circuit diagram of a memory cell of the memory circuit of FIG. 2, in accordance with some embodiments.

FIG. 5 illustrates a flowchart of a method for operating the memory circuit of FIG. 2 to perform part of a MAC operation, in accordance with some embodiments.

FIG. 6 and FIG. 7 each illustrate a layout for forming a memory cell of the memory circuit of FIG. 2 configured with a CFET structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An AI accelerator is a class of specialized hardware to accelerate machine learning workloads for deep neural network (DNN) processing, which are typically neural networks that involve massive memory accesses and highly-parallel but simple computations. A neural network refers to a plurality of interconnected processing nodes that enable the analysis of data to compare an input to “trained” data. Trained data refers to computational analysis of properties of known data to develop models to use to compare input data. AI accelerators can be based on application-specific integrated circuits (ASIC) which include multiple processing elements (PEs) (or processing circuits) arranged spatially or temporally to perform a part of the multiply-and-accumulate (MAC) operation. The MAC operation is performed based on input activation states (sometimes referred to as input data elements) and weights (sometimes referred to as weight data elements), and then summed together to provide output activation states. The input activation states and the output activation states are typically referred to as an input and output of the PEs, respectively.

The present disclosure provides various embodiments of an AI accelerator configured for neural network processing such as, for example, a binary/binarized neural network (BNN). In a BNN, the real value of each variable (e.g., input data elements, weight data elements) is binarized into two possible binary (or binarized) values: +1 or −1. In various embodiments, the disclosed AI accelerator is implemented as a memory circuit that includes a memory array with a plural number of memory cells, and each of the memory cells includes a multi-port static random access memory (SRAM) cell, e.g., an eight-transistor (8T) SRAM cell. The 8T SRAM cell can include a first pair of pass-gate transistors and a second pair of pass-gate transistors. All four pass-gate transistors may share a common conductivity type. The first pair of pass-gate transistors may have their respective gate terminals connected to a first word line (e.g., WL), and the second pair of pass-gate transistors may have their respective gate terminals connected to a second word line (e.g., WLB). The first and second word lines, WL and WLB, can receive complementary logic states of a WL assertion or enablement signal.

In one aspect, the first and second word lines, WL and WLB, can respectively receive a first combination of logic states for the WL assertion signal, corresponding to a first binarized value of the weight data element, or respectively receive a second combination of logic states for the WL assertion signal, corresponding to a second binarized value of the weight data element. The 8T SRAM cell can store a first combination of logic states in its two internal nodes, respectively, corresponding to a first binarized value of the input data element, or store a second combination of logic states in its two internal nodes, respectively, corresponding to a second binarized value of the input data element. In another aspect, the first and second word lines, WL and WLB, can respectively receive a first combination of logic states for the WL assertion signal, corresponding to a first binarized value of the input data element, or respectively receive a second combination of logic states for the WL assertion signal, corresponding to a second binarized value of the input data element. The 8T SRAM cell can store a first combination of logic states in its two internal nodes, respectively, corresponding to a first binarized value of the weight data element, or store a second combination of logic states in its two internal nodes, respectively, corresponding to a second binarized value of the weight data element.

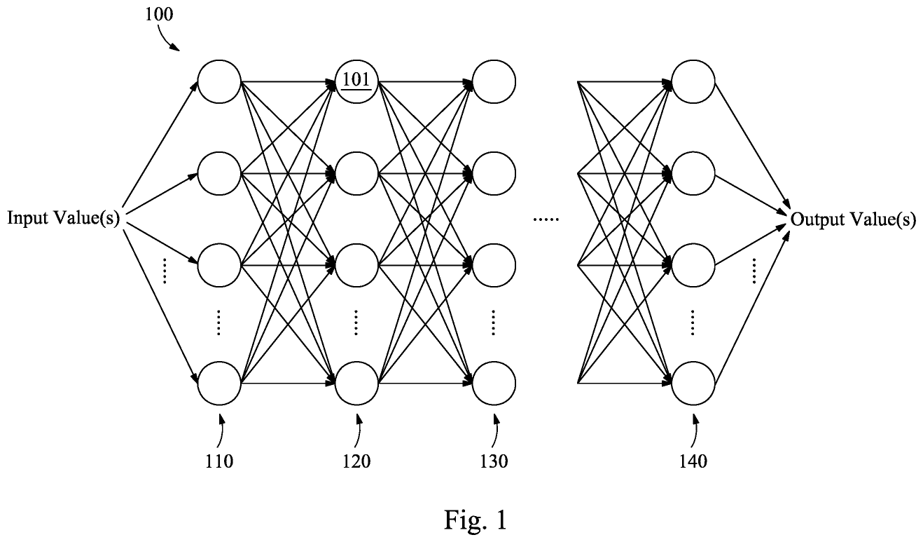

FIG. 1 illustrates an example neural network 100, in accordance with various embodiments. As shown, the neural network 100 includes four layers 110, 220, 130, and 140, where the layers 110 and 140 are referred to as an input layer and output layer, respectively, and the layers 220 to 130 are each referred to as a hidden layer. Each of the layers can include a number of neurons. In general, the hidden layers of the neural network 100 can largely be viewed as layers of neurons that each receive (e.g., weighted) outputs from the neurons of preceding layer(s) of neurons in a mesh-like interconnection structure between layers. The connection from the output of a particular preceding neuron to the input of another subsequent neuron is set according to the influence or effect that the preceding neuron is to have on the subsequent neuron (for simplicity, only one neuron 101 and the connections are labeled). In the illustrative example of FIG. 1, the output value of the preceding neuron is multiplied by the weight of its connection to the subsequent neuron to determine the particular stimulus that the preceding neuron presents to the subsequent neuron.

A neuron's total input stimulus corresponds to the combined stimulation of all of its weighted input connections. According to various implementations, if a neuron's total input stimulus exceeds some threshold, the neuron is triggered to perform some, e.g., linear or non-linear mathematical function on its input stimulus. The output of the mathematical function corresponds to the output of the neuron which is subsequently multiplied by the respective weights of the neuron's output connections to its following neurons. Generally, the more connections between neurons, the more neurons per layer and/or the more layers of neurons, the greater the intelligence the network is capable of achieving. As such, neural networks for actual, real-world artificial intelligence applications are characterized by large numbers of neurons and large numbers of connections between neurons. Extremely large numbers of calculations (not only for neuron output functions but also weighted connections) are therefore involved in processing information through a neural network.

In general, a neural network computes weights to perform computation on input data (input stimulus or input), or computes input data to perform computation on weights. Machine learning currently relies on the computation of dot-products and absolute difference of vectors, typically computed with multiply-accumulate (MAC) operations performed on the parameters, input data and weights. The computation of large and deep neural networks typically involves so many data elements, and thus it is not practical to store them in processor cache. Accordingly, these data elements are usually stored in a memory. Thus, machine learning is very computationally intensive with the computation and comparison of many different data elements. The computation of operations within a processor is orders of magnitude faster than the transfer of data elements between the processor and main memory resources. Placing all the data elements closer to the processor in caches is prohibitively expensive for the great majority of practical systems due to the memory sizes needed to store the data elements. Thus, the transfer of data elements becomes a major bottleneck for AI computations. As the data sets increase, the time and power/energy a computing system uses for moving data elements around can end up being multiples of the time and power used to actually perform computations.

In this regard, a Compute-In-Memory (CIM) circuit has been proposed to perform such MAC operations. A CIM circuit instead conducts data processing in situ within a suitable memory circuit. The CIM circuit suppresses the latency for data/program fetch and output results upload in corresponding memory (e.g. a memory array), thus solving the memory (or von Neumann) bottleneck of conventional computers. Another key advantage of the CIM circuit is the high computing parallelism, thanks to the specific architecture of the memory array, where computation can take place along several current paths at the same time. The CIM circuit also benefits from the high density of multiple memory arrays with computational devices, which generally feature excellent scalability and the capability of 3D integration. As a non-limiting example, the CIM circuit targeted for various machine learning applications can perform the MAC operations locally within the memory (i.e., without having to send data elements to a host processor) to enable higher throughput dot-product of neuron activation and weight matrices, while still providing higher performance and lower energy compared to computation by the host processor.

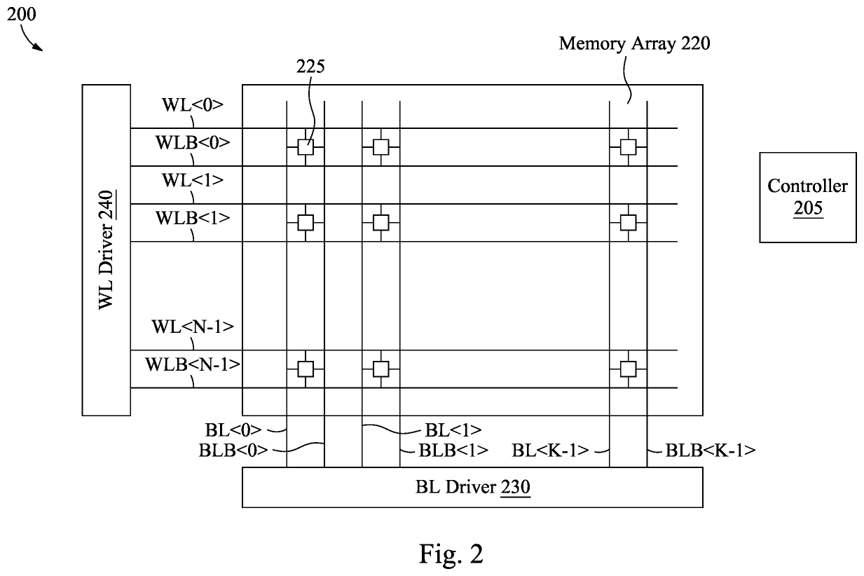

FIG. 2 illustrates a block diagram of a memory circuit (or CIM circuit) 200, in accordance with various embodiments. The memory circuit 200 is configured to perform MAC operations on binarized input data elements and binarized weight data elements, through implementing each memory cell of the memory circuit 200 as an 8T SRAM cell. However, each memory cell of the disclosed memory circuit 200 can be implemented as any of various other suitable memory cells, while remaining within the scope of the present disclosure. Further, it should be appreciated that the block diagram of FIG. 2 has been simplified for illustrative purposes, and thus, the memory circuit 200 can include any of various other components, while remaining within the scope of the present disclosure.

As shown, the memory circuit 200 include a memory controller 205 and a memory array 220. The memory array 220 includes a plurality of storage circuits or memory cells 225 arranged in two- or three-dimensional arrays. Each memory cell 225 may be coupled to a corresponding group of word lines WLs and a corresponding group of bit lines BLs. The memory controller 205 may write data to or read data from the memory array 220 according to electrical signals through word lines WLs and bit lines BLs. In other embodiments, the memory circuit 200 includes more, fewer, or different components than shown in FIG. 2.

The memory array 220 is a hardware component that stores data. For example, the memory array 220 is embodied as a semiconductor memory device. The memory array 220 includes a plurality of storage circuits or memory cells 225. The memory array 220 includes a number of word lines WLs, e.g., WL<0>, WL<1> . . . . WL<N−1>, and the corresponding number of complementary word lines WLBs, e.g., WLB<0>, WLB<1> . . . . WLB<N−1>, disposed across multiple rows, respectively. The number “N” can be any integer. Each of the word lines WLs and the complementary word lines WLBs can extend in a first direction. The memory array 220 includes a number of bit lines BLs, e.g., BL<0>, BL<1> . . . . BL<K−1>, and the corresponding number of complementary bit lines BLBs, e.g., BLB<0>, BLB<1> . . . . BLB<K−1>, disposed across multiple columns, respectively. The number “K” can be any integer. Each of the bit lines BLs and the complementary bit lines BLBs can extend in a second direction.

In some embodiments, each memory cell 225 is embodied as an 8T SRAM cell or other type of memory cell. For example, in addition to six transistors that operatively form a latch, the memory cell 225 can include a first pair of pass-gate transistors coupling the latch to a pair of bit lines BL and BLB, respectively, and a second pair of pass-gate transistors coupling the latch to the pair of bit lines BL and BLB, respectively. The first pair of pass-gate transistors can have their gate terminals commonly connected to a first word line WL, and the second pair of pass-gate transistors can their gate terminals commonly connected to a second word line WLB. In various embodiments of the present disclosure, the first pair of pass-gate transistors and the second pair of pass-gate transistors are configured to be alternately activated (or turned on). Upon being activated, access to the internal nodes of the memory cell 225 can be allowed. The memory array 220 can include additional lines (e.g., select lines, reference lines, reference control lines, power rails, etc.), while remaining within the scope of the present disclosure.

The memory controller 205 is a hardware component that can control operations of the memory array 220. For example, the memory controller 205 may include a BL controller (or driver circuit) 230 and a WL controller (or driver circuit) 240, as shown in FIG. 2. The BL driver circuit 230 and the WL driver circuit 240 may each be embodied as one or more logic circuits, one or more analog circuits, or a combination of them. In some embodiments, the WL driver circuit 240 is a circuit that can provide a voltage or current (e.g., a WL assertion signal with one or more pulses) through an asserted word line WL of the memory array 220, and the BL driver circuit 230 is a circuit that can provide or sense a voltage or current through one or more bit lines BL of the memory array 220. In some other embodiments, the memory circuit 200 can include more, fewer, or different components than shown in FIG. 2. For example, the memory circuit 200 can further include a timing controller that can provide control signals or clock signals to synchronize operations of the BL driver circuit 230 and the WL driver circuit 240.

According to various embodiments of the present disclosure, the memory circuit 200 (or the WL driver circuit 240) can include one or more registers corresponding to each of the rows of the memory array 220, or coupled to the corresponding pair of WL and WLB. The one or more registers can each be configured to store one bit of the input data element (e.g., being binarized) in one aspect, or one bit of the weight data element (e.g., being binarized) in another aspect. The input or weight data element (e.g., temporality stored in the registers) can be applied to a selected one of the memory cells 225 through the corresponding pair of word lines WL and WLB. Upon being selected (or activated through the word lines WL and WLB), the memory cell 225 can multiply the weight or input data element stored therein with the input or weight data element received through the word lines WL and WLB. As such, the memory cell 225 can produce a multiplied bit-line current proportional to a product of the received input/weight data element and the stored weight/input data element. The memory circuit 200 (or the BL driver circuit 230) can include a number of accumulators corresponding to the columns, respectively, where each of the accumulators is configured to sum a number of the multiplied bit-line currents read from the bit lines BL and BLB along that column. For example, the multiplied bit-line currents from the activated memory cells 225 in each column are coupled to the corresponding pair of bit lines BL and BLB in that column producing summed multiplied bit-line current for each column. The memory circuit 200 (or the BL driver circuit 230) can further include at least one accumulator to sum the summed multiplied bit-line current across multiple (e.g., all) columns.

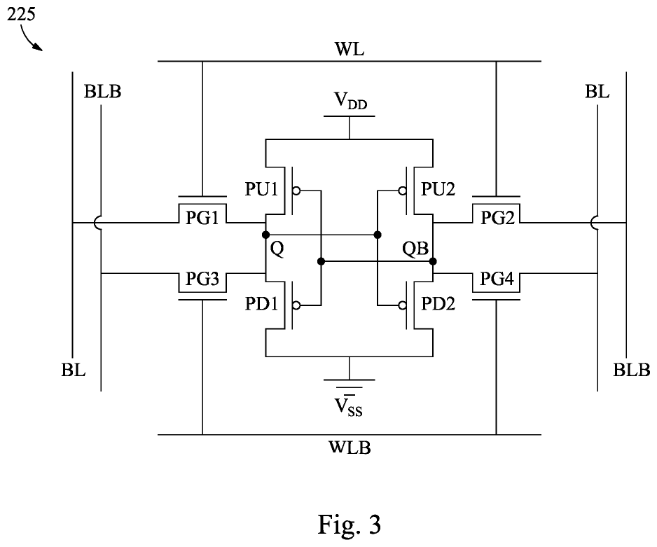

FIG. 3 illustrates an example circuit diagram of the memory cell 225, which is implemented as an SRAM cell (hereinafter “SRAM cell 225”), in accordance with one embodiment. In the illustrative example of FIG. 3, the SRAM cell 225 includes eight transistors: a first pass-gate transistor (PG1), a second pass-gate transistor (PG2), a third pass-gate transistor (PG3), a fourth pass-gate transistor (PG4), a first pull-up transistor (PU1), a second pull-up transistor (PU2), a first pull-down transistor (PD1), and a second pull-down transistor (PD2). However, it should be understood that the SRAM memory cell 225 can include any suitable number of transistors (e.g., 10) while remaining within the scope of the present disclosure.

In some embodiments, the transistors PG1, PG2, PG3, PG4, PD1, and PD2 may each be an n-type metal-oxide-semiconductor field-effect transistors (MOSFET), and the transistors PU1 and PU2 may each be a p-type MOSFET. The transistors PU1 and PD1 can be coupled between VDD and VSS, and serves as a first inverter; and the transistors PU2 and PD2 can be coupled between VDD and VSS, and serves as a second inverter, where the first inverter and the second inverter are cross-coupled to each other. For example, commonly connected source/drain terminals of the transistors PU1 and PD1 are connected to gate terminals of the transistors PU2 and PD2, operatively forming internal node Q; and commonly connected source/drain terminals of the transistors PU2 and PD2 are connected to gate terminals of the transistors PU1 and PD1, operatively forming internal node QB.

The transistors PG1 and PG3 have their first source/drain terminals connected to the internal node Q; and the transistors PG2 and PG4 have their first source/drain terminals connected to the internal node QB. Further, the transistors PG1 and PG3 have their second source/drain terminals connected to a first bit line BL and a second bit line BLB, respectively; and the transistors PG2 and PG4 have their second source/drain terminals connected to the second bit line BLB and the first bit line BL, respectively. The transistors PG1 and PG2 have their gate terminals commonly connected to a first word line WL; and the transistors PG3 and PG4 have their gate terminals commonly connected to a second word line WLB.

In one embodiment of the present disclosure (based on the circuit diagram of FIG. 3), the first word line WL and the second word line WLB receive complementary logic states of a WL assertion signal, respectively. For example, the first word line WL can receive the WL assertion signal with a logic 1, while the second word line WL can concurrently receive the WL assertion signal with a logic 0; and for another example, the first word line WL can receive the WL assertion signal with a logic 0, while the second word line WL can concurrently receive the WL assertion signal with a logic 1. Such different combinations of logic states received on the word lines WL and WLB can correspond to respective binarized value of an input data element configured to activate the memory cell 225. Given the word lines WL and WLB applied with logic 1 and logic 0, respectively, the binarized value of the input data element may correspond to +1; and given the word lines WL and WLB applied with logic 0 and logic 1, respectively, the binarized value of the input data element may correspond to −1. That is, the input data element=+1, when WL=1 and WLB=0; and the input data element=−1, when WL=0 and WLB=1.

Further, the internal nodes Q and QB can store complementary logic states of a weight data element. For example, the internal node Q can store the weight data element with a logic 1, while the internal node QB can store the weight data element with a logic 0; and for another example, the internal node Q can store the weight data element with a logic 0, while the internal node QB can store the weight data element with a logic 1. Such different combinations of logic states respectively stored in the internal nodes Q and QB can correspond to respective binarized value of the weight data element. Given the internal nodes Q and QB storing logic 1 and logic 0, respectively, the binarized value of the weight data element may correspond to +1; and given the internal nodes Q and QB storing logic 0 and logic 1, respectively, the binarized value of the weight data element may correspond to −1. That is, the weight data element=+1, when Q=1 and QB=0; and the weight data element=−1, when Q=0 and QB=1.

Table I below summarizes the respective binarized values of the input data element and the weight data element, and corresponding example voltages present on the bit lines BL and BLB, respectively. Table I further illustrates a product (or a binarized multiplication) of the input data element and the weight data element, given the corresponding binarized value of the input data element and the corresponding binarized value of the weight data element.

TABLE I

| INPUT | WEIGHT | V_{BL} | V_{BLB} | MULTIPLICATION |
|---|---|---|---|---|
| −1 | −1 | V_{DD} | V_{DD} − ΔV | +1 |
| −1 | +1 | V_{DD} − ΔV | V_{DD} | −1 |
| +1 | −1 | V_{DD} − ΔV | V_{DD} | −1 |
| +1 | +1 | V_{DD} | V_{DD} − ΔV | +1 |

In another embodiment of the present disclosure (based on the circuit diagram of FIG. 3), the first word line WL and the second word line WLB receive complementary logic states of a WL assertion signal, respectively. For example, the first word line WL can receive the WL assertion signal with a logic 1, while the second word line WL can concurrently receive the WL assertion signal with a logic 0; and for another example, the first word line WL can receive the WL assertion signal with a logic 0, while the second word line WL can concurrently receive the WL assertion signal with a logic 1. Such different combinations of logic states received on the word lines WL and WLB can correspond to respective binarized value of a weight data element configured to activate the memory cell 225. Given the word lines WL and WLB applied with logic 1 and logic 0, respectively, the binarized value of the weight data element may correspond to +1; and given the word lines WL and WLB applied with logic 0 and logic 1, respectively, the binarized value of the weight data element may correspond to −1. That is, the weight data element=+1, when WL=1 and WLB=0; and the weight data element=−1, when WL=0 and WLB=1.

Further, the internal nodes Q and QB can store complementary logic states of an input data element. For example, the internal node Q can store the input data element with a logic 1, while the internal node QB can store the input data element with a logic 0; and for another example, the internal node Q can store the input data element with a logic 0, while the internal node QB can store the input data element with a logic 1. Such different combinations of logic states respectively stored in the internal nodes Q and QB can correspond to respective binarized value of the input data element. Given the internal nodes Q and QB storing logic 1 and logic 0, respectively, the binarized value of the input data element may correspond to +1; and given the internal nodes Q and QB storing logic 0 and logic 1, respectively, the binarized value of the input data element may correspond to −1. That is, the input data element=+1, when Q=1 and QB=0; and the input data element=−1, when Q=0 and QB=1.

Table II below summarizes the respective binarized values of the input data element and the weight data element, and corresponding example voltages present on the bit lines BL and BLB, respectively. Table II further illustrates a product (or a binarized multiplication) of the input data element and the weight data element, given the corresponding binarized value of the input data element and the corresponding binarized value of the weight data element.

TABLE II

| INPUT | WEIGHT | V_{BL} | V_{BLB} | MULTIPLICATION |
|---|---|---|---|---|
| −1 | −1 | V_{DD} | V_{DD} − ΔV | +1 |
| −1 | +1 | V_{DD} − ΔV | V_{DD} | −1 |
| +1 | −1 | V_{DD} − ΔV | V_{DD} | −1 |
| +1 | +1 | V_{DD} | V_{DD} − ΔV | +1 |

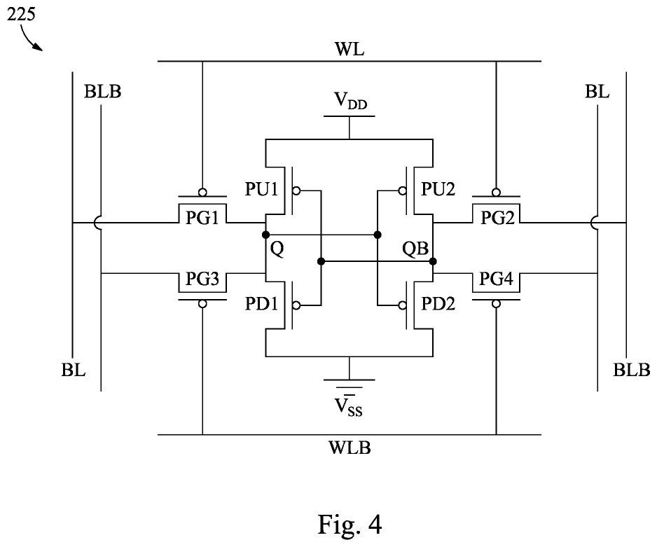

FIG. 4 illustrates another example circuit diagram of the memory cell 225, which is implemented as an SRAM cell (hereinafter “SRAM cell 225”), in accordance with one embodiment. In the illustrative example of FIG. 4, the SRAM cell 225 includes eight transistors: a first pass-gate transistor (PG1), a second pass-gate transistor (PG2), a third pass-gate transistor (PG3), a fourth pass-gate transistor (PG4), a first pull-up transistor (PU1), a second pull-up transistor (PU2), a first pull-down transistor (PD1), and a second pull-down transistor (PD2). However, it should be understood that the SRAM memory cell 225 can include any suitable number of transistors (e.g., 10) while remaining within the scope of the present disclosure.

In some embodiments, the transistors PG1, PG2, PG3, PG4, PU1, and PU2 may each be a p-type metal-oxide-semiconductor field-effect transistors (MOSFET), and the transistors PD1 and PD2 may each be an n-type MOSFET. The transistors PU1 and PD1 can be coupled between VDD and VSS, and serves as a first inverter; and the transistors PU2 and PD2 can be coupled between VDD and VSS, and serves as a second inverter, where the first inverter and the second inverter are cross-coupled to each other. For example, commonly connected source/drain terminals of the transistors PU1 and PD1 are connected to gate terminals of the transistors PU2 and PD2, operatively forming internal node Q; and commonly connected source/drain terminals of the transistors PU2 and PD2 are connected to gate terminals of the transistors PU1 and PD1, operatively forming internal node QB.

The transistors PG1 and PG3 have their first source/drain terminals connected to the internal node Q; and the transistors PG2 and PG4 have their first source/drain terminals connected to the internal node QB. Further, the transistors PG1 and PG3 have their second source/drain terminals connected to a first bit line BL and a second bit line BLB, respectively; and the transistors PG2 and PG4 have their second source/drain terminals connected to the second bit line BLB and the first bit line BL, respectively. The transistors PG1 and PG2 have their gate terminals commonly connected to a first word line WL; and the transistors PG3 and PG4 have their gate terminals commonly connected to a second word line WLB.

In one embodiment of the present disclosure (based on the circuit diagram of FIG. 4), the first word line WL and the second word line WLB receive complementary logic states of a WL assertion signal, respectively. For example, the first word line WL can receive the WL assertion signal with a logic 1, while the second word line WL can concurrently receive the WL assertion signal with a logic 0; and for another example, the first word line WL can receive the WL assertion signal with a logic 0, while the second word line WL can concurrently receive the WL assertion signal with a logic 1. Such different combinations of logic states received on the word lines WL and WLB can correspond to respective binarized value of an input data element configured to activate the memory cell 225. Given the word lines WL and WLB applied with logic 1 and logic 0, respectively, the binarized value of the input data element may correspond to +1; and given the word lines WL and WLB applied with logic 0 and logic 1, respectively, the binarized value of the input data element may correspond to −1. That is, the input data element=+1, when WL=1 and WLB=0; and the input data element=−1, when WL=0 and WLB=1.

Further, the internal nodes Q and QB can store complementary logic states of a weight data element. For example, the internal node Q can store the weight data element with a logic 1, while the internal node QB can store the weight data element with a logic 0; and for another example, the internal node Q can store the weight data element with a logic 0, while the internal node QB can store the weight data element with a logic 1. Such different combinations of logic states respectively stored in the internal nodes Q and QB can correspond to respective binarized value of the weight data element. Given the internal nodes Q and QB storing logic 0 and logic 1, respectively, the binarized value of the weight data element may correspond to +1; and given the internal nodes Q and QB storing logic 1 and logic 0, respectively, the binarized value of the weight data element may correspond to −1. That is, the weight data element=+1, when Q=0 and QB=1; and the weight data element=−1, when Q=1 and QB=0.

Table III below summarizes the respective binarized values of the input data element and the weight data element, and corresponding example voltages present on the bit lines BL and BLB, respectively. Table III further illustrates a product (or a binarized multiplication) of the input data element and the weight data element, given the corresponding binarized value of the input data element and the corresponding binarized value of the weight data element.

TABLE III

| INPUT | WEIGHT | V_{BL} | V_{BLB} | MULTIPLICATION |
|---|---|---|---|---|
| −1 | −1 | ΔV | 0 | +1 |
| −1 | +1 | 0 | ΔV | −1 |
| +1 | −1 | 0 | ΔV | −1 |
| +1 | +1 | ΔV | 0 | +1 |

In another embodiment of the present disclosure (based on the circuit diagram of FIG. 4), the first word line WL and the second word line WLB receive complementary logic states of a WL assertion signal, respectively. For example, the first word line WL can receive the WL assertion signal with a logic 1, while the second word line WL can concurrently receive the WL assertion signal with a logic 0; and for another example, the first word line WL can receive the WL assertion signal with a logic 0, while the second word line WL can concurrently receive the WL assertion signal with a logic 1. Such different combinations of logic states received on the word lines WL and WLB can correspond to respective binarized value of a weight data element configured to activate the memory cell 225. Given the word lines WL and WLB applied with logic 1 and logic 0, respectively, the binarized value of the weight data element may correspond to +1; and given the word lines WL and WLB applied with logic 0 and logic 1, respectively, the binarized value of the weight data element may correspond to −1. That is, the weight data element=+1, when WL=1 and WLB=0; and the weight data element=−1, when WL=0 and WLB=1.

Further, the internal nodes Q and QB can store complementary logic states of an input data element. For example, the internal node Q can store the input data element with a logic 1, while the internal node QB can store the input data element with a logic 0; and for another example, the internal node Q can store the input data element with a logic 0, while the internal node QB can store the input data element with a logic 1. Such different combinations of logic states respectively stored in the internal nodes Q and QB can correspond to respective binarized value of the input data element. Given the internal nodes Q and QB storing logic 0 and logic 1, respectively, the binarized value of the input data element may correspond to +1; and given the internal nodes Q and QB storing logic 1 and logic 0, respectively, the binarized value of the input data element may correspond to −1. That is, the input data element=+1, when Q=0 and QB=1; and the input data element=−1, when Q=1 and QB=0.

Table IV below summarizes the respective binarized values of the input data element and the weight data element, and corresponding example voltages present on the bit lines BL and BLB, respectively. Table II further illustrates a product (or a binarized multiplication) of the input data element and the weight data element, given the corresponding binarized value of the input data element and the corresponding binarized value of the weight data element.

TABLE IV

| INPUT | WEIGHT | V_{BL} | V_{BLB} | MULTIPLICATION |
|---|---|---|---|---|
| −1 | −1 | ΔV | −0 | +1 |
| −1 | +1 | −0 | ΔV | −1 |
| +1 | −1 | −0 | ΔV | −1 |
| +1 | +1 | ΔV | −0 | +1 |

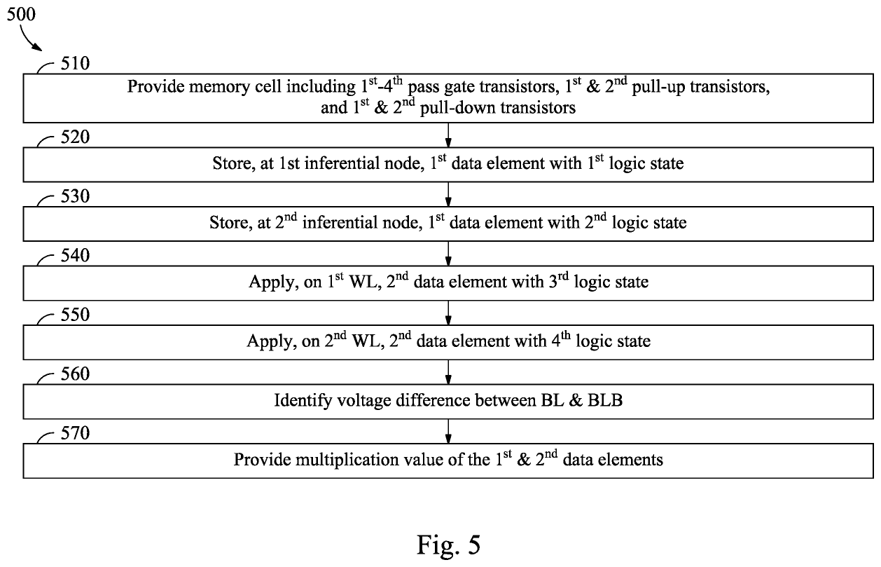

FIG. 5 illustrates a flow chart of a method 500 for operating memory circuits to produce a multiplication value on a first data element and a second data element, in accordance with some embodiments. Each of the first and second data elements can be applied, stored, or otherwise provided as a binarized value, e.g., +1 or −1. The example method 500 can be performed by the above-discussed memory circuit 200 (FIG. 2). As such, the following embodiment of the method 500 can be described in conjunction with but not limited to at least FIG. 2, 3, or 4. The illustrated embodiment of the method 500 is provided as an example and does not intent to limit the scope of the present disclosure. Therefore, it shall be understood that any of a variety of the operations of the method 500 may be omitted, re-sequenced, and/or added while remaining within the scope of the present disclosure.

The method 500 starts with operation 510 of providing a memory cell including a first pull-up transistor, a second pull-up transistor, a first pull-down transistor, a second pull-down transistor, a first pass-gate transistor, a second pass-gate transistor, a third pass-gate transistor, and a fourth pass-gate transistor. In some embodiments, the first pull-up transistor and the first pull-down transistor, with their source/drain terminals commonly connected to each other at a first internal node, operatively serve as a first inverter; and the second pull-up transistor and the second pull-down transistor, with their source/drain terminals commonly connected to each other at a second internal node, operatively serve as a second inverter. The first and second inverters are cross-coupled with each other. The first and second pass-gate transistors have their gate terminals connected to a first word line; and the third and fourth pass-gate transistors have their gate terminals connected to a second word line. The first pass-gate transistor is coupled between the first internal node and a first bit line; the second pass-gate transistor is coupled between the second internal node and a second bit line; the third pass-gate transistor is coupled between the first internal node and the second bit line; and the fourth pass-gate transistor is coupled between the second internal node and the first bit line.

Using the memory cell 225 of FIG. 3 as a representative example, the first and second pass-gate transistors (PG1 and PG2) have their gate terminals connected to a first word line (WL), and the third and fourth pass-gate transistors (PG3 and PG4) have their gate terminals connected to a second word line (WLB). The first pass-gate transistor is coupled between a first internal node (Q) of the memory cell and a first bit line (BL), the second pass-gate transistor is coupled between a second internal node (QB) of the memory cell and a second bit line, or bit line bar (BLB), the third pass-gate transistor is coupled between the first internal node of the memory cell and the second bit line BLB, and the fourth pass-gate transistor is coupled between the second internal node of the memory cell and the first bit line BL.

The method 500 continues to operation 520 of storing, at the first internal node, a first data element with a first logic state, and to operation 530 of storing, at the second internal node, the first data element with a second logic state logically opposite to the first logic state. In some embodiments, one of the first or second logic state represents a sign of the first data element (e.g., a weight data element) being binarized.

Continuing with the above example, the first internal node (Q) can store a weight data element in logic 1, while the second internal node (QB) can store the weight data element in logic 0, in one aspect; or the first internal node (Q) can store a weight data element in logic 0, while the second internal node (QB) can store the weight data element in logic 1, in another aspect. When the internal nodes Q and QB store logic 1 and logic 0, respectively, the memory cell is configured to store a binarized value of the weight data element with +1; and when the internal nodes Q and QB store logic 0 and logic 1, respectively, the memory cell is configured to store a binarized value of the weight data element with −1.

The method 500 continues to operation 540 of applying, on the first word line, a second data element with a third logic state, and to operation 550 of applying, on the second word line, the second data element with a fourth logic state logically opposite to the third logic state. In some embodiments, one of the third or fourth logic state represents a sign of the second data element (e.g., an input data element) being binarized. The WL driver circuit 240 can apply the second data element on the first word line and second word line with opposite logic states, respectively, according to some embodiments.

Continuing with the above example, the first word line (WL) can be applied (or activated) with the input data element having logic 1, while the second word line (WLB) is applied (or deactivated) with the input data element having logic 0, in one aspect; or the first word line (WL) can be applied (or deactivated) with the input data element having logic 0, while the second word line (WLB) is applied (or activated) with the input data element having logic 1, in another aspect. When the word lines WL and WLB are applied with logic 1 and logic 0, respectively, the memory cell is configured to receive a binarized value of the input data element with +1; and when the word lines WL and WLB are applied with logic 0 and logic 1, respectively, the memory cell is configured to receive a binarized value of the input data element with −1.

The method 500 continues to operation 560 of identifying a voltage difference present between the bit line and the bit line bar, and to operation 570 of providing a multiplication value of the first data element and the second data element. In some embodiments, the multiplication value is also binarized, with a sign determined according to the sign of the binarized first data element and the sign of the binarized second data element. The BL driver circuit 230, which may include one or more sense amplifiers, can sense or otherwise identify the voltage difference between the bit line and bit line bar, and based on a sign of the voltage difference, determine a sign of the multiplication value, according to some embodiments.

Continuing with the above example, when the binarized value of the weight data element and the binarized value of the input data element are provided as −1 and −1, respectively, the transistors PG1 and PG2 are turned off, the transistors PG3 and PG4 are turned on, the internal node Q is at logic 0, and the internal QB is at logic 1. Given the internal node Q is at logic 0, the second bit line BLB, which has been previously pre-charged to logic 1 (or VDD)), can be discharged through the turned-on transistor PG3 and a voltage present on the second bit line BLB may drop to VDD-AV. Given the internal node QB is at logic 1, the first bit line BL may remain at the pre-charged voltage level (VDD), even the transistor PG4 being turned on. Accordingly, the BL driver circuit 230 can identify that the voltages present on the bit lines BL (V_{BL}) and BLB (V_{BLB}) are V_{DD} and V_{DD}−ΔV, respectively. Based on a sign of the voltage difference (e.g., V_{BL}−V_{BLB}), which is positive in the current example, the BL driver circuit 230 can determine the sign of the binarized multiplication value as positive, i.e., +1.

When the binarized value of the weight data element and the binarized value of the input data element are provided as +1 and −1, respectively, the transistors PG1 and PG2 are turned off, the transistors PG3 and PG4 are turned on, the internal node Q is at logic 1, and the internal QB is at logic 0. Given the internal node QB is at logic 0, the first bit line BL, which has been previously pre-charged to logic 1 (or V_{DD}), can be discharged through the turned-on transistor PG4 and a voltage present on the first bit line BL may drop to V_{DD}−ΔV. Given the internal node Q is at logic 1, the second bit line BLB may remain at the pre-charged voltage level (V_{DD})), even the transistor PG3 being turned on. Accordingly, the BL driver circuit 230 can identify that the voltages present on the bit lines BL (V_{BL}) and BLB (V_{BLB}) are V_{DD}−ΔV and V_{DD}, respectively. Based on the sign of the voltage difference (e.g., V_{BL}−V_{BLB}), which is negative in the current example, the BL driver circuit 230 can determine the sign of the binarized multiplication value as negative, i.e., −1.

When the binarized value of the weight data element and the binarized value of the input data element are provided as −1 and +1, respectively, the transistors PG1 and PG2 are turned on, the transistors PG3 and PG4 are turned off, the internal node Q is at logic 0, and the internal QB is at logic 1. Given the internal node Q is at logic 0, the first bit line BL, which has been previously pre-charged to logic 1 (or V_{DD}), can be discharged through the turned-on transistor PG1 and a voltage present on the first bit line BL may drop to V_{DD}−ΔV. Given the internal node QB is at logic 1, the second bit line BLB may remain at the pre-charged voltage level (V_{DD}), even the transistor PG2 being turned on. Accordingly, the BL driver circuit 230 can identify that the voltages present on the bit lines BL (V_{BL}) and BLB (V_{BLB}) are V_{DD}−ΔV and V_{DD}, respectively. Based on the sign of the voltage difference (e.g., V_{BL}−V_{BLB}), which is negative in the current example, the BL driver circuit 230 can determine the sign of the binarized multiplication value as negative, i.e., −1.

When the binarized value of the weight data element and the binarized value of the input data element are provided as +1 and +1, respectively, the transistors PG3 and PG4 are turned off, the transistors PG1 and PG2 are turned on, the internal node Q is at logic 1, and the internal QB is at logic 0. Given the internal node QB is at logic 1, the second bit line BL, which has been previously pre-charged to logic 1 (or V_{DD}), can be discharged through the turned-on transistor PG2 and a voltage present on the first bit line BL may drop to V_{DD}−ΔV. Given the internal node Q is at logic 1, the first bit line BL may remain at the pre-charged voltage level (V_{DD}), even the transistor PG1 being turned on. Accordingly, the BL driver circuit 230 can identify that the voltages present on the bit lines BL (V_{BL}) and BLB (V_{BLB}) are V_{DD} and V_{DD}−ΔV, respectively. Based on the sign of the voltage difference (e.g., V_{BL}−V_{BLB}), which is positive in the current example, the BL driver circuit 230 can determine the sign of the binarized multiplication value as positive, i.e., +1.

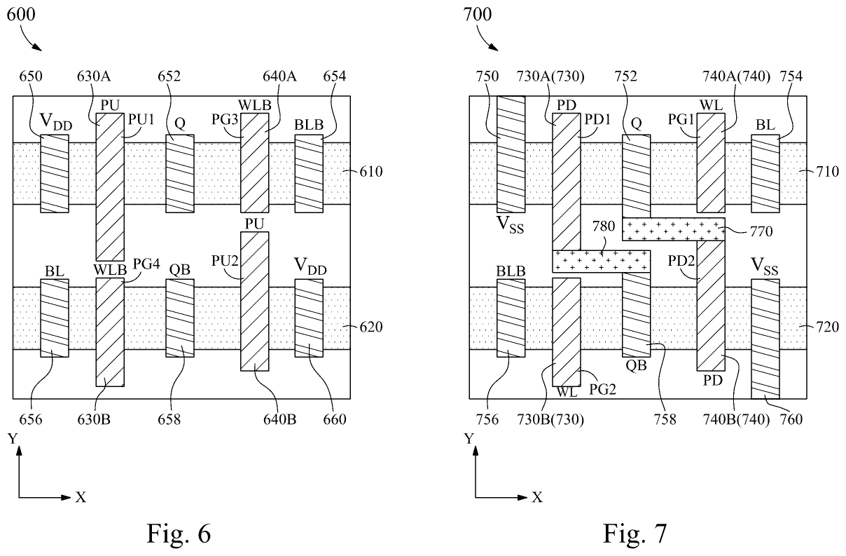

FIG. 6 and FIG. 7 respectively illustrate layouts 600 and 700 that can be collectively utilized to form the memory cell 225 (e.g., FIG. 3) configured in a complementary field-effect transistor (CFET) structure. In general, a CFET is one type of a gate-all-around (GAA) field-effect transistor, which includes a plural number of nanostructures (e.g., nanosheets or nanowires) vertically stacked on top of one another. P-type and n-type GAA FETs are typically formed on the same horizontal plane over a substrate and are separated by isolation structures. In contrast, a CFET is commonly fabricated by vertically stacking a p-type GAA FET and an n-type GAA FET on top of each other. This stacking configuration of n-type and p-type transistors in a single structure eliminates the need for an n-to-p separation, reduces the active area footprint, and increases the transistor density within a chip. This stacking concept is not limited to GAA FETs; for example, CFETs can be formed with FinFET devices or with a combination of GAA FETs and FinFETs.

The CFET structure can include a number of first transistors disposed at a first level on the frontside of a substate, and a number of second transistors despised at a second, upper level on the frontside of the substrate. In some embodiments, each of these first and second transistors is configured as a GAA FET, while some of the first transistors have a first conductive type and some of the second transistors have a second conductive type. In some other embodiments, each of the first and second transistors can be formed as other type of transistor structures while remaining within the scope of the present disclosure.

Generally, each of the layouts 600 and 700 can include a number of patterns configured for forming respective structures, and thus, such patterns of the disclosed layout are herein referred to as the structures to be formed, respectively, in the following discussion. For example, the layout 600 is configured to form structures of the first transistors at the first level on the frontside; and the layout 700 is configured to form structures of the second transistors at the second level on the frontside. It should be understood that each of the layouts 200 to 500 has been simplified for illustrative purposes, and thus, can include any of various other patterns while remaining within the scope of the present disclosure.

Referring first to FIG. 6, the layout 600 can include patterns for forming active regions 610 and 620 and gate structures 630 and 640, respectively. The active regions 610 and 620 may extend in the X-direction; and the gate structures 630 and 640 may extend in the Y-direction. Each of the active regions 610 and 620 may be formed as a fin structure or a stack structure extending along the X-direction, and each of the gate structures 630 and 640 may be formed to extend in the Y-direction to traverse the active regions 630 and 640. Each of the gate structures 630 and 640 can be divided into multiple gate sections. For example, the gate structure 630 is divided into gate sections 630A and 630B, and the gate structure 640 is divided into gate sections 640A and 640B.

Referring next to FIG. 7, the layout 700 can include patterns for forming active regions 710 and 720 and gate structures 730 and 740, respectively. The active regions 710 and 720 may extend in the X-direction; and the gate structures 730 and 740 may extend in the Y-direction. Each of the active regions 710 and 720 may be formed as a fin structure or a stack structure extending along the X-direction, and each of the gate structures 730 and 740 may be formed to extend in the Y-direction to traverse the active regions 730 and 740. Each of the gate structures 730 and 740 can be divided into multiple gate sections. For example, the gate structure 730 is divided into gate sections 730A and 730B, and the gate structure 740 is divided into gate sections 740A and 740B.

In some embodiments, the active regions 610 and 710 are vertically aligned with each other, the active regions 620 and 720 are vertically aligned with each other, the gate structures 630 and 730 are vertically aligned with each other, and the gate structures 640 and 740 are vertically aligned with each other. Further, the active regions 610 and 710 may be physically formed as a single structure (sometimes referred to as “active region 610/710”), the active regions 620 and 720 may be physically formed as a single structure (sometimes referred to as “active region 620/720”), the gate structures 730 and 730 may be physically formed as a single structure (sometimes referred to as “gate structure 630/730”), and the gate structures 640 and 740 may be physically formed as a single structure (sometimes referred to as “gate structure 640/740”).

For example, the active region 610/710 and active region 620/720 can each be first formed as a stack structure protruding from the frontside surface of a substrate. The stack may include a number of first semiconductor nanostructures (e.g., first nanosheets) extending along the X-direction and vertically separated from each other, and a number of second semiconductor nanostructures (e.g., second nanosheets) extending along the X-direction and vertically separated from each other. The first nanosheets are positioned at the first level, and the second nanosheets are positioned at the second level. According to some embodiments of the present disclosure, the first nanosheets, formed based on a lower portion of the active region 610/710 or a lower portion of the active region 620/720, can partially form the first transistors formed at the first level; and the second nanosheets, formed based on an upper portion of the active region 610/710 or an upper portion of the active region 620/720, can partially form the second transistors formed at the second level. Further, the first nanosheets and the second nanosheets can be vertically aligned with but separated from each other, with at least one dielectric layer interposed therebetween.

Next, respective portions of the first and second nanosheets in each of the stacks that are overlaid by the gate structure 630/730 and the gate structure 640/740, which are initially formed as a number of dummy (e.g., polysilicon) gate structures, respectively, may remain. Other portions of the first nanosheets are replaced with a number of first epitaxial structures, and other portions of the second nanosheets are replaced with a number of second epitaxial structures. According to some embodiments of the present disclosure, some of the first epitaxial structures (at the first level) may be formed with a p-type conductivity, while some of the first epitaxial structures (at the first level) may be formed with an n-type conductivity; and the second epitaxial structures (at the second level) may be formed with an n-type conductivity. The first epitaxial structures can operatively form respective source/drain terminals of the first transistors at the first level, and the second epitaxial structures can operatively form respective source/drain terminals of the second transistors at the second level.

Next, each of the dummy gate structures 630/730 and 640/740 can be replaced by a corresponding active (e.g., metal) gate structure to form the first and second transistors. According to some embodiments of the present disclosure, each of the active gate structures can include a lower portion and an upper portion corresponding to the first level and the second level, respectively. For example, the lower portion of at least one of the active gate structures may include one or more first work function metals configured for forming a gate terminal of one of the first transistors with the p-type conductivity, and the upper portion of the at lease one active gate structure may include one or more second work function metals configured for forming a gate terminal of one of the second transistors with the n-type conductivity.

As a brief overview, the transistors PU1, PU2, PG3, and PG4 of the memory cell 225 (FIG. 3) can be formed at the first level based on the layout 600 (as indicated in FIG. 6), and the transistors PD1, PD2, PG1, and PG2 of the memory cell 225 (FIG. 3) can be formed at the second level based on the layout 700 (as indicated in FIG. 7). Accordingly, the gate sections 640A and 630B (FIG. 6) can operatively serve as a part of the second word line WLB, and the gate sections 740A and 730B (FIG. 7) can operatively serve as a part of the first word line WL. Further, in some embodiments, the transistors PU1 and PU2 at the first level can be formed with the p-type conductivity, the transistors PG3 and PG4 at the first level can be formed with the n-type conductivity, and the transistors PD1, PD2, PG1, and PG2 at the second level can be formed with the n-type conductivity.

Referring again to FIG. 6, the layout 600 can further include patterns for forming source/drain contact structures 650, 652, 654, 656, 658, and 660, respectively. Similarly in FIG. 7, the layout 700 can further include patterns for forming source/drain contact structures 750, 752, 754, 756, 758, and 760, respectively. Such source/drain contact structures 650 to 660 and 750 to 760 are each sometimes referred to as MD. In general, each of these MDs 650 to 660 and 750 to 760 is configured to electrically connect to the source/drain terminal of a corresponding transistor. For example, each of the MDs 650 to 660 and 750 to 760 can be physically coupled to or wrap around the epitaxial structure of a corresponding transistor. In some embodiments, each of the MDs 650 to 660 and 750 to 760 can laterally extend along the same direction as the gate structures 630-640 and 730-740, e.g., the Y-direction.

For example, in FIG. 6, the MD 650 is connected to a first source/drain terminal of the transistor PU1, which can be electrically connected to V_{DD}; the MD 652 is connected to a second source/drain terminal of the transistor PU1 and a first source/drain terminal of the transistor PG3, which can operatively serve as a part of the internal node Q; the MD 654 is connected to a second source/drain terminal of the transistor PG3, which can be electrically connected to the BLB; the MD 656 is connected to a first source/drain terminal of the transistor PG4, which can be electrically connected to the BL; the MD 658 is connected to a second source/drain terminal of the transistor PG4 and a first source/drain terminal of the transistor PU2, which can operatively serve as a part of the internal node QB; the MD 660 is connected to a second source/drain terminal of the transistor PU2, which can be electrically connected to VDD.

For another example, in FIG. 7, the MD 750 is connected to a first source/drain terminal of the transistor PD1, which can be electrically connected to VSS; the MD 752 is connected to a second source/drain terminal of the transistor PD1 and a first source/drain terminal of the transistor PG1, which can operatively serve as a part of the internal node QB; the MD 754 is connected to a second source/drain terminal of the transistor PG1, which can be electrically connected to the BL; the MD 756 is connected to a first source/drain terminal of the transistor PG2, which can be electrically connected to the BLB; the MD 758 is connected to a second source/drain terminal of the transistor PG2 and a first source/drain terminal of the transistor PD2, which can operatively serve as a part of the internal node QB; and the MD 760 is connected to a second source/drain terminal of the transistor PD2, which can be electrically connected to VSS.

In some embodiments, the MD 652 (FIG. 6) and MD 752 (FIG. 7) may be connected to each other through a first internal via structure (not shown), and the MD 658 (FIG. 6) and MD 758 (FIG. 7) may be connected to teach other through a second internal via structure (not shown). Stated another way, the first internal via structure can vertically extend from the first level to the second level to connect the MD 652 to the MD 752, and the second internal via structure can vertically extend from the first level to the second level to connect the MD 658 to the MD 658. The layout 700 can further include patterns for forming internal contact structures 770 and 780, respectively. The internal contact structure 770 can electrically couple the gate section 740B to the MD 752, and the internal contact structure 780 can electrically couple the gate section 730A to the MD 758. In some embodiments, each of the internal contact structures 770 and 780 can laterally extend along the same direction as the active regions 610-620 and 710-720, e.g., the X-direction.

As such, the internal node Q, at which the respective source/drain terminals of the transistors PU1, PD1, PG1, and PG3, and the respective gate terminals of the transistors PU2 and PD2 are connected to one another, can be operatively formed through the MD 652, the MD 652, the first internal via structure vertically interposed therebetween, and the internal contact structure 780. Similarly, the internal node QB, at which the respective source/drain terminals of the transistors PU2, PD2, PG2, and PG4, and the respective gate terminals of the transistors PU1 and PD1 are connected to one another, can be operatively formed based on the MD 658, the MD 758, the second via structure vertically interposed therebetween, and the internal contact structure 770.

In one aspect of the present disclosure, a memory circuit is disclosed. The circuit includes a memory array including a plurality of memory cells, wherein each of the plurality of memory cells includes a plurality of transistors, and coupled to a first word line and a second word line, and wherein each of the plurality of memory cells is configured to receive a first data element, store a second data element, and provide a multiplication value of the first data element and the second data element. The first word line is configured to receive a first logic state corresponding to the first data element being binarized, and the second word line is configured to receive a second logic state corresponding to the first data element being binarized. A first internal node among the plurality of transistors is configured to store a first logic state corresponding to the second data element being binarized, and a second internal node among the plurality of transistors is configured to store a second logic state corresponding to the second data element being binarized.

In another aspect of the present disclosure, a memory circuit is disclosed. The circuit includes a first memory cell including a first pull-up transistor, a second pull-up transistor, a first pull-down transistor, a second pull-down transistor, a first pass-gate transistor, a second pass-gate transistor, a third pass-gate transistor, and a fourth pass-gate transistor. The first and second pass-gate transistors of the first memory cell have their respective gate terminals connected to a first word line, and the third and fourth pass-gate transistors of the first memory cell have their respective gate terminals connected to a second word line. The first word line is configured to receive a first logic state corresponding to a first data element being binarized, and the second word line is configured to receive a second logic state corresponding to the first data element being binarized. A first internal node of the first memory cell, accessible through one of its first or second pass-gate transistor, is configured to store a first logic state corresponding to a second data element being binarized, and a second internal node of the first memory cell, accessible through one of its third or fourth pass-gate transistor, is configured to store a second logic state corresponding to the second data element being binarized.

In yet another aspect of the present disclosure, a method for operating a memory circuit is disclosed. The method includes providing a memory cell including a first pull-up transistor, a second pull-up transistor, a first pull-down transistor, a second pull-down transistor, a first pass-gate transistor, a second pass-gate transistor, a third pass-gate transistor, and a fourth pass-gate transistor, wherein the first and second pass-gate transistors have their gate terminals connected to a first word line, and the third and fourth pass-gate transistors have their gate terminals connected to a second word line, and wherein the first pass-gate transistor is coupled between a first internal node of the memory cell and a bit line, the second pass-gate transistor is coupled between a second internal node of the memory cell and a bit line bar, the third pass-gate transistor is coupled between the first internal node of the memory cell and the bit line bar, and the fourth pass-gate transistor is coupled between the second internal node of the memory cell and the bit line. The method includes storing, at the first internal node, a first data element with a first logic state. The method includes storing, at the second internal node, the first data element with a second logic state logically opposite to the first logic state, wherein one of the first or second logic state represents a first sign of the first data element being binarized. The method includes applying, on the first word line, a second data element with a third logic state. The method includes applying, on the second word line, the second data element with a fourth logic state logically opposite to the third logic state, wherein one of the third or fourth logic state represents a second sign of the second data element being binarized. The method includes identifying a voltage difference present between the bit line and the bit line bar. The method includes providing a multiplication value of the first data element and the second data element, wherein the multiplication value, being binarized, has a third sign determined according to the first sign and the second sign.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, +20%, or +30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A circuit, comprising:
a memory array including a plurality of memory cells, wherein each of the plurality of memory cells includes a plurality of transistors, and coupled to a first word line and a second word line, and wherein each of the plurality of memory cells is configured to receive a first data element, store a second data element, and provide a multiplication value of the first data element and the second data element;
wherein the first word line is configured to receive a first logic state corresponding to the first data element being binarized, and the second word line is configured to receive a second logic state corresponding to the first data element being binarized; and
wherein a first internal node among the plurality of transistors is configured to store a first logic state corresponding to the second data element being binarized, and a second internal node among the plurality of transistors is configured to store a second logic state corresponding to the second data element being binarized.

2. The circuit of claim 1, wherein the first data element includes an input data element, and the second data element includes a weight data element.

3. The circuit of claim 1, wherein the first data element includes a weight data element, and the second data element includes an input data element.

4. The circuit of claim 1, wherein the plurality of transistors of each of the memory cells includes a first pass-gate transistor, a second pass-gate transistor, a third pass-gate transistor, a fourth pass-gate transistor, a first pull-up transistor, a first pull-down transistor, a second pull-up transistor, and a second pull-down transistor.

5. The circuit of claim 4, wherein the first and second pass-gate transistors have their gate terminals connected to the first word line, and the third and fourth pass-gate transistors have their gate terminals connected to the second word line.

6. The circuit of claim 5, wherein the first and third pass-gate transistors have their first source/drain terminals connected to the first internal node, and the second and fourth pass-gate transistors have their first source/drain terminals connected to the second internal node.

7. The circuit of claim 6, wherein the first and third pass-gate transistors have their second source/drain terminals connected to a first bit line and a first bit line bar, respectively, and the second and fourth pass-gate transistors have their second source/drain terminals connected to the first bit line bar and the first bit line, respectively.

8. The circuit of claim 4, wherein the first to fourth pass-gate transistors have a same conductivity.

9. The circuit of claim 1, wherein the first logic state of the first data element represents a first sign of the first data element, and second logic state of the first data element represents a second sign of the first data element.

10. The circuit of claim 9, wherein the first logic state of the second data element represents a first sign of the second data element, and second logic state of the second data element represents a second sign of the second data element.

11. The circuit of claim 10, wherein the multiplication value of the first data element and the second data element is determined according to one of the first or second sign of the first data element and one of the first or second sign of the second data element.

12. A circuit, comprising:
a first memory cell including a first pull-up transistor, a second pull-up transistor, a first pull-down transistor, a second pull-down transistor, a first pass-gate transistor, a second pass-gate transistor, a third pass-gate transistor, and a fourth pass-gate transistor;
wherein the first and second pass-gate transistors of the first memory cell have their respective gate terminals connected to a first word line, and the third and fourth pass-gate transistors of the first memory cell have their respective gate terminals connected to a second word line;
wherein the first word line is configured to receive a first logic state corresponding to a first data element being binarized, and the second word line is configured to receive a second logic state corresponding to the first data element being binarized; and
wherein a first internal node of the first memory cell, accessible through one of its first or second pass-gate transistor, is configured to store a first logic state corresponding to a second data element being binarized, and a second internal node of the first memory cell, accessible through one of its third or fourth pass-gate transistor, is configured to store a second logic state corresponding to the second data element being binarized.

13. The circuit of claim 12, wherein the first data element includes an input data element, and the second data element includes a weight data element.

14. The circuit of claim 12, wherein the first data element includes a weight data element, and the second data element includes an input data element.

15. The circuit of claim 12, further comprising:
a second memory cell including a first pull-up transistor, a second pull-up transistor, a first pull-down transistor, a second pull-down transistor, a first pass-gate transistor, a second pass-gate transistor, a third pass-gate transistor, and a fourth pass-gate transistor;
wherein the first and second pass-gate transistors of the second memory cell have their respective gate terminals connected to a third word line, and the third and fourth pass-gate transistors of the second memory cell have their respective gate terminals connected to a third word line;
wherein the third word line is configured to receive a first logic state of a third data element, and the second word line is configured to receive a second logic state of the third data element; and
wherein a first internal node of the second memory cell, accessible through one of its first or second pass-gate transistor, is configured to store the first logic state of the second data element, and a second internal node of the second memory cell, accessible through one of its third or fourth pass-gate transistor, is configured to store the second logic state of the second data element.

16. The circuit of claim 15, wherein the first memory cell and the second memory cell are coupled between a first pair of complementary bit lines and a second pair of complementary bit lines.

17. The circuit of claim 16, wherein one of the first pair of complementary bit lines is coupled to one of the second pair of complementary bit lines, with the other of the first pair of complementary bit lines coupled to the other of the second pair of complementary bit lines.

18. A method, comprising:
providing a memory cell including a first pull-up transistor, a second pull-up transistor, a first pull-down transistor, a second pull-down transistor, a first pass-gate transistor, a second pass-gate transistor, a third pass-gate transistor, and a fourth pass-gate transistor, wherein the first and second pass-gate transistors have their gate terminals connected to a first word line, and the third and fourth pass-gate transistors have their gate terminals connected to a second word line, and wherein the first pass-gate transistor is coupled between a first internal node of the memory cell and a bit line, the second pass-gate transistor is coupled between a second internal node of the memory cell and a bit line bar, the third pass-gate transistor is coupled between the first internal node of the memory cell and the bit line bar, and the fourth pass-gate transistor is coupled between the second internal node of the memory cell and the bit line;
storing, at the first internal node, a first data element with a first logic state;
storing, at the second internal node, the first data element with a second logic state logically opposite to the first logic state, wherein one of the first or second logic state represents a first sign of the first data element being binarized;
applying, on the first word line, a second data element with a third logic state;
applying, on the second word line, the second data element with a fourth logic state logically opposite to the third logic state, wherein one of the third or fourth logic state represents a second sign of the second data element being binarized;
identifying a voltage difference present between the bit line and the bit line bar; and
providing a multiplication value of the first data element and the second data element, wherein the multiplication value, being binarized, has a third sign determined according to the first sign and the second sign.

19. The method of claim 18, wherein the first data element includes an input data element, and the second data element includes a weight data element.

20. The method of claim 18, wherein the first data element includes a weight data element, and the second data element includes an input data element.
